(19) United States
(12) Patent Application Publication
(10) Pub. No.: US 2011/0013783 A1
(43) Pub. Date: Jan. 20, 2011

(54) OVERTONE PRODUCTION DEVICE, ACOUSTIC DEVICE, AND OVERTONE PRODUCTION METHOD

(75) Inventor: Keitaro Sugawara, Kawagoe (JP)

Correspondence Address: YOUNG & THOMPSON, 209 Madison Street, Suite 500, Alexandria, VA, 22314, US

(73) Assignee: PIONEER CORPORATION, Tokyo (JP)

(21) Appl. No.: 12/933,579

(22) PCT Filed: Mar. 19, 2008
(86) PCT No.: PCT/JP2008/055067

§ 371 Date: Sep. 20, 2010

(51) Int. Cl. H03G 5/00

(52) U.S. Cl. 381/98

(57) ABSTRACT

When boosting treble, first a signal X(T) of a fundamental tone component which is to be a subject of overtone production is extracted by a fundamental tone extraction filter section 210 from the signal which is to be the subject for being boosted. Next, a clip level calculation section 221 calculates a clip level based upon the signal X(T). And a comparison calculation section 222 performs clipping processing upon the signal X(T) on the basis of the clip level W(T), and generates a signal that includes overtone components. Consequently, it is possible to produce overtones whose processed contents are suitable for digital signal processing, without performing any division computation, and, when boosting the treble register, appropriate overtones can be reliably produced in a manner which does not give the listener any sense of discomfort.

### TECHNICAL FIELD

The present invention relates to an overtone production device, to an acoustic device, to an overtone production method, to an overtone production program, and to a recording medium upon which said overtone production program is recorded.

### BACKGROUND ART

In recent years, acoustic devices that replay audio contents recorded in digital format have become widespread. In many cases, in order to reduce its file size, this type of audio contents data is subjected to compression processing by a method such as MP3 (MPEG (Moving Picture Expert Group) Audio Layer-3), WMA (Windows Media audio), or the like. With this type of compression processing a general practice is to cut the treble register, which is considered to be difficult for a human being to hear.

Thus, for a mode in which the listener is to experience little sense of discomfort, various types of technique have been proposed for reinforcing the treble register in the audio signal that is directly generated from the audio contents data by generating overtones of components of a predetermined frequency range. Among such techniques, a technique has been proposed with which it is possible to generate overtones reliably even at low signal levels (refer to Patent Document 1, hereinafter referred to as the “prior art example”).

With this technique according to the prior art example, an amplification ratio for the audio signal is calculated on the basis of the signal levels of the components in the audio signal of the predetermined frequency range, so that clipping processing is performed at a predetermined clip level. Next, the audio signal is multiplied by this amplification ratio, and the signal which is the result of this multiplication is clipped at the predetermined clip level. As a result, a signal is generated which includes the overtones in the audio signal. And the signal which is the result of clipping is divided by the above amplification ratio, so as its signal level is returned to the level before amplification. Subsequently, it is arranged to extract the overtone components in the desired frequency range, and to add them to the above audio signal.

Patent Document #1: WO 2007/116755 A1

### DISCLOSURE OF THE INVENTION

### Problems to be Solved by the Invention

While overtone production by digital signal processing is indeed accomplished with the above described technique according to the prior art example, not only does this digital signal processing take some considerable time, but also it includes division by the amplification ratio, which is a value that can change. Moreover, while this type of digital signal processing is generally performed using a DSP (Digital Signal Processor), if division, not by a constant value that is determined in advance but rather by a variable value, is to be performed by a DSP having a structure which is adapted to execute addition, subtraction, and multiplication, then it becomes necessary to execute a large amount of processing, and the calculation load upon the DSP becomes large.

Due to this, even in a case in which the digital signal processing is performed by using a DSP, there has been a great demand for a technique which can reliably produce appropriate overtones when reinforcing the treble register in a way in which the burden of calculation upon the DSP is kept down and yet the listener experiences little sense of discomfort. To meet this requirement is proposed as one of the problems which the present invention can solve.

The present invention has been conceived in consideration of the circumstances described above, and takes it as its object to provide an overtone production device and an overtone production method which are suited to digital signal processing, and which moreover can reliably generate an appropriate overtone when boosting the treble register, in a way which does not impart any sense of discomfort to the listener.

Furthermore, the present invention takes it as its object to provide an acoustic device which can replay audio in which the treble register is reinforced, in a manner in which there is little sense of discomfort from the point of view of the listener.

### Means for Solving the Problems

When the present invention is considered from a first standpoint, it is an overtone production device which produces overtones of a component of a predetermined frequency range included in an audio signal, characterized by comprising: an extraction part configures to extract said component of said predetermined frequency range from said audio signal; a calculation part configures to calculate a clip level corresponding to the signal level of the signal extracted by said extraction part a clipping part configures to generate a clipped signal by performing clipping processing upon said extracted signal, on the basis of the clip level calculated by said calculation part; and said calculation part configures to calculate a new clip level value on the basis of the value of the error between the result of multiplying the current value of the signal level of said extracted signal by a predetermined reference value, and the current value of said clip level.

And, when the present invention is considered from a second standpoint, it is an acoustic device, characterized by comprising: an overtone production device according to the present invention, which produces overtones of a component of a predetermined frequency range included in an audio signal; an overtone extraction means which extracts a predetermined overtone component in the overtone signal produced by said overtone production device; and an overtone addition means that adds together said audio signal and said signal extracted by said overtone extraction means.

Moreover, when the present invention is considered from a third standpoint, it is an overtone production method, characterized by comprising: an extraction process of extracting a component of a predetermined frequency range from an audio signal; a calculation process of calculating a clip level corresponding to the signal level of the signal extracted by said extraction part; a clipping process of performing clipping processing upon said extracted signal, on the basis of the clip level calculated by said calculation process and in that said calculation process, a new clip level value is calculated on the basis of the value of the error between the result of multiplying the current value of the signal level of said extracted signal by a predetermined reference value, and the current value of said clip level.

Furthermore, when the present invention is considered from a fourth standpoint, it is an overtone production program, characterized by causing a calculation means to execute an overtone production method according to the present invention.

Finally, when the present invention is considered from a fifth standpoint, it is a recording medium, characterized by an overtone production program according to the present invention being recorded thereupon so as to be readable by a calculation means.

### BRIEF DESCRIPTION OF THE DRAWINGS

FIG. 1 is a figure schematically showing the structure of an acoustic device according to an embodiment of the present invention;

FIG. 2 is a block diagram showing the structure of a treble boost unit of FIG. 1;

FIG. 3 is a block diagram for explaining the structure of an overtone production device of FIG. 2;

FIG. 4 is a block diagram for explaining the structure of an odd overtone production section of FIG. 3;

FIG. 5 is a figure for explaining an example of the waveform of a signal generated by the odd overtone production section having the FIG. 4 structure;

FIG. 6 is a figure for explaining an example of the frequency distribution of the signal generated by the odd overtone production section having the FIG. 4 structure;

FIG. 7 is a figure for explaining an example of the waveform of a signal generated by an even overtone production section of FIG. 3;

FIG. 8 is a figure for explaining an example of the frequency distribution of the signal generated by the FIG. 3 even overtone production section;

FIG. 9 is a block diagram for explaining the structure of a weighted addition section of FIG. 3;

FIG. 10 is a figure for explaining an example of the frequency distribution of the signal generated by the overtone production device having the FIG. 3 structure;

FIG. 11 is a figure for explaining an example of the frequency distribution of a signal generated by the treble boost unit having the FIG. 2 structure;

FIG. 12 is a block diagram for explaining the structure of an analog processing unit of FIG. 1; and

FIG. 13 is a figure for explaining signal frequency distribution variation as the acoustic device of FIG. 1 operates.

### BEST MODES FOR CARRYING OUT THE INVENTION

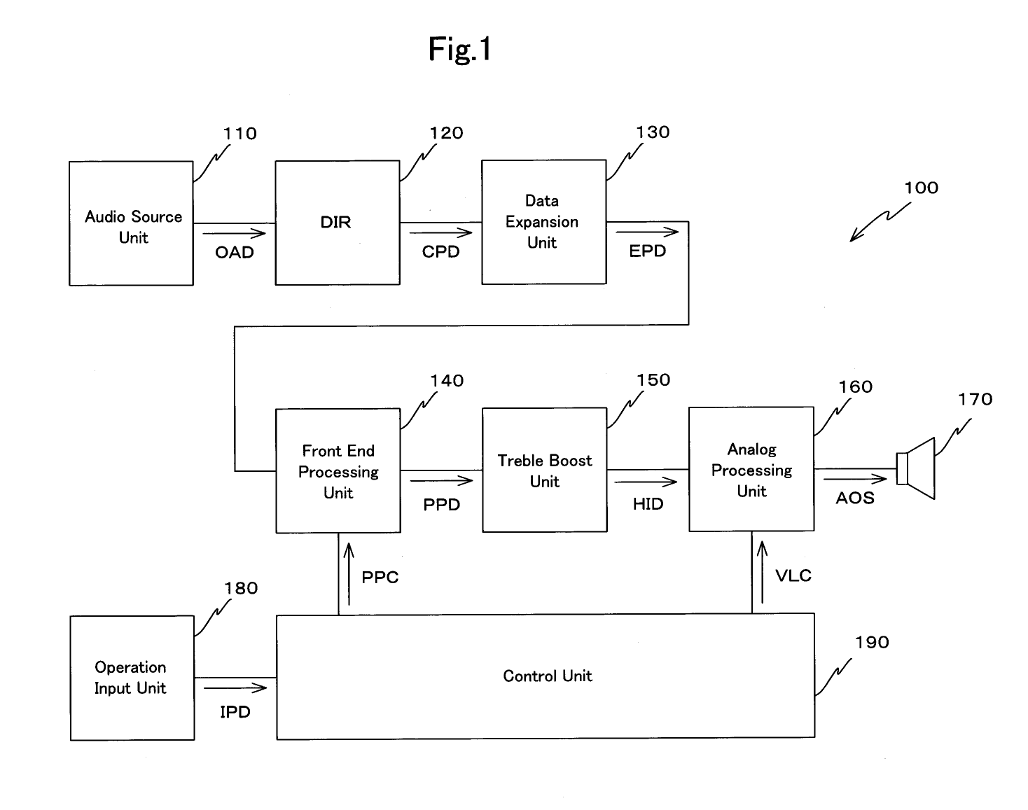

In the following, an embodiment of the present invention will be described with reference to FIGS. 1 through 13. It should be understood that, in the drawings, the same reference symbols are assigned to elements which are the same or equivalent, and duplicated explanation is omitted.

### [Structure]

In FIG. 1, the structure of an acoustic device 100 which is an embodiment of the present invention is schematically shown as a block diagram. As shown in the FIG. 1, the acoustic device 100 comprises an audio source unit 110, a DIR (Digital Interface Receiver) 120, and a data expansion unit 130. Moreover, the acoustic device 100 comprises a front end processing unit 140, a treble boost unit 150, an analog processing unit 160, and a speaker unit 170. Furthermore, the acoustic device 100 comprises an operation input unit 180 and a control unit 190.

A signal OAD corresponding to audio contents data that has been data compressed so as to be compatible with MP3 or WMA is outputted from the abovementioned audio source unit 110. This type of audio contents data may, for example, be recorded upon a recording medium such as a DVD (Digital Versatile Disk), a CD (Compact Disk), a hard disk or the like, and the result of reading it out from such a recording medium is that it is outputted from the audio source unit 110 as the signal OAD.

The DIR 120 described above receives the signal OAD from the audio source unit 110. And the DIR 120 converts the signal OAD into a signal CPD that is in a format that can be processed by the subsequent signal processing system. The signal CPD that is generated in this manner is sent to the data expansion unit 130.

The data expansion unit 130 described above receives the signal CPD from the DIR 120. And the data expansion unit 130 performs data decompression processing upon the signal CPD to cancel its data compression. The result of this data expansion in this manner is sent as a signal EPD to the front end processing unit 140.

The front end processing unit 140 described above receives the signal EPD from the data expansion unit 130. And, according to a front end processing control command PPC from the control unit 190, the front end processing unit 140 performs front end processing upon the signal EPD, such as mixing processing and so on. The result of this front end processing is sent to the treble boost unit 150 as a signal PPD.

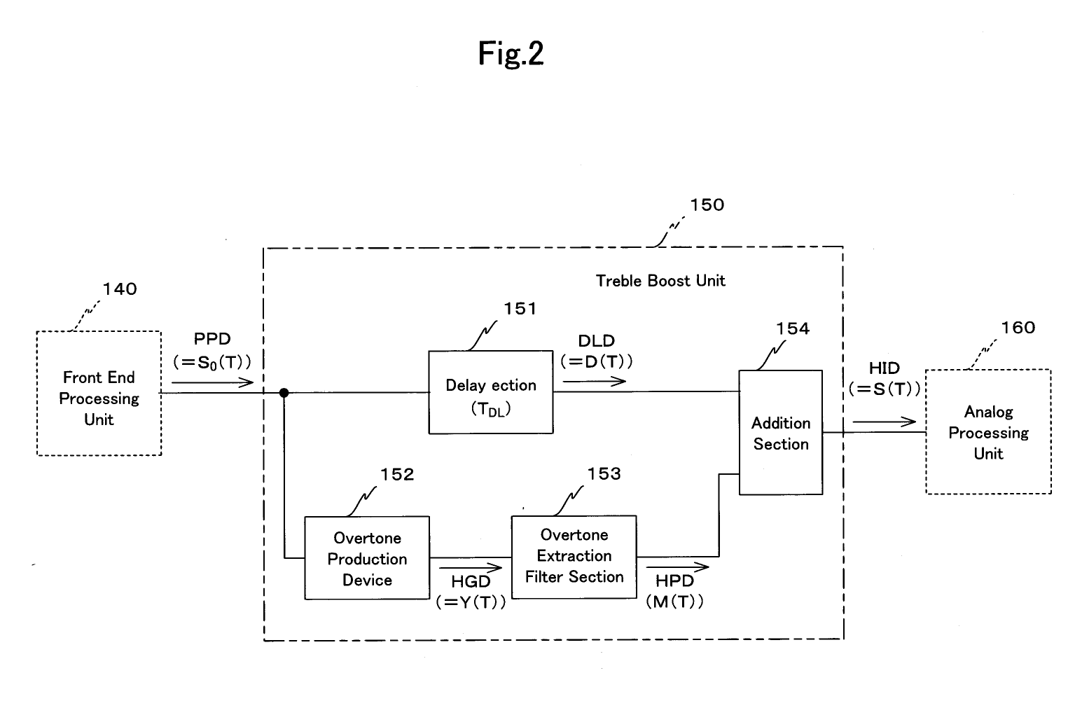

The treble boost unit 150 described above receives this signal PPD from the front end processing unit 140. And the treble boost unit 150 performs treble boost processing by generating overtones of a predetermined frequency component in the signal PPD. As shown in FIG. 2, the treble boost unit 150 comprises a delay section 151 and an overtone production device 152. Moreover, the treble boost unit 150 comprises an overtone extraction filter section 153 which serves as an overtone extraction means, and an addition section 154 which serves as an overtone addition means.

The delay section 151 described above receives the signal PPD (=S₀(T)) from the front end processing unit 140. Here, the time point T is given by T=n·τ (where N is the sample number, and τ is the sampling period).

And the delay section 151 generates a signal DLD (=D(T)), which is the signal S₀(T) delayed by just a processing time period T_{DL} due to the overtone production device 152 and the overtone extraction filter section 153. Here, the relationship between the signal D(T) and the signal S₀(T) is given by the following Equation (1):

D(T)=S₀(T−T_{DL}) (1)

As a result, synchronization may be anticipated between the signal D(T) and a signal HPD (=M(T)) which is outputted from the overtone extraction filter section 153 which will be described hereinafter. The signal DLD (=D(T)) that is generated in this manner is sent to the addition section 154.

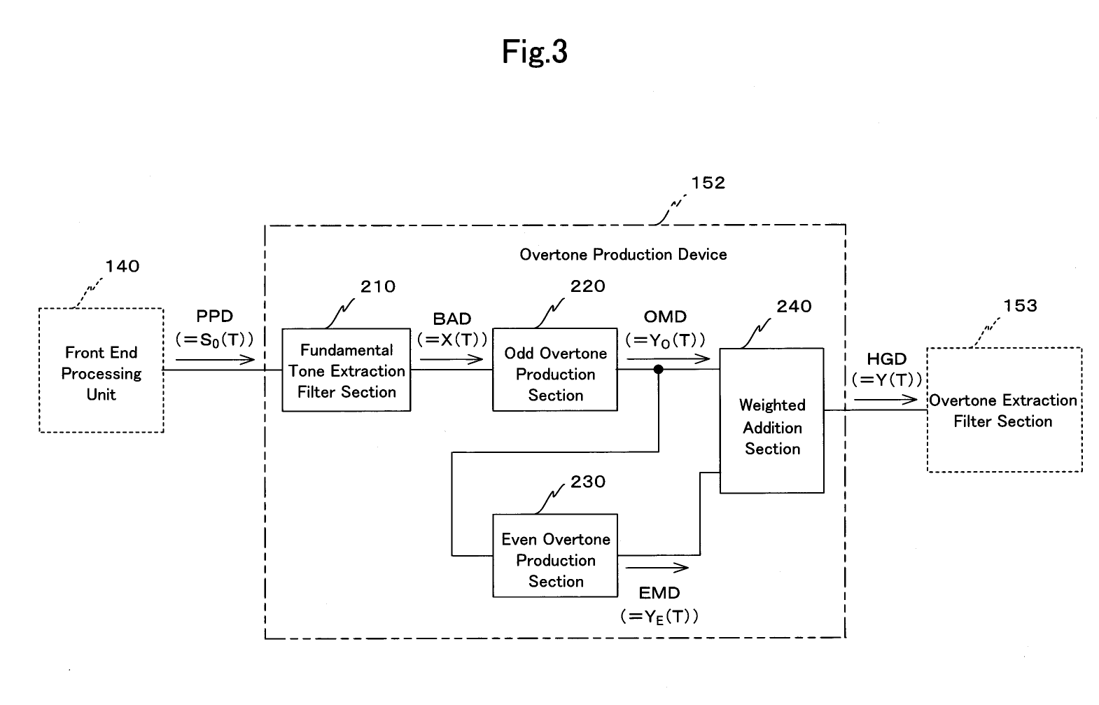

The overtone production device 152 described above receives the signal PPD (=S₀(T)) from the front end processing unit 140. And the overtone production device 152 generates a signal HGD (=Y(T)) which includes overtones of components of the signal PPD in a predetermined frequency range. As shown in FIG. 3, the overtone production device 152 comprises a fundamental tone extraction filter section 210 that serves as an extraction means, and an odd overtone production section 220. Furthermore, the overtone production device 152 comprises an even overtone production section 230 that serves as an even overtone production means, and a weighted addition section 240 that serves as an addition means.

The fundamental tone extraction filter section 210 described above receives the signal PPD (=S₀(T)) from the front end processing unit 140. And the fundamental tone extraction filter section 210 extracts the component which is to be the subject of overtone generation from this signal PPD. The fundamental tone extraction filter section 210 sends the result of this extraction to the odd overtone production section 220 as a signal BAD (=X(T)).

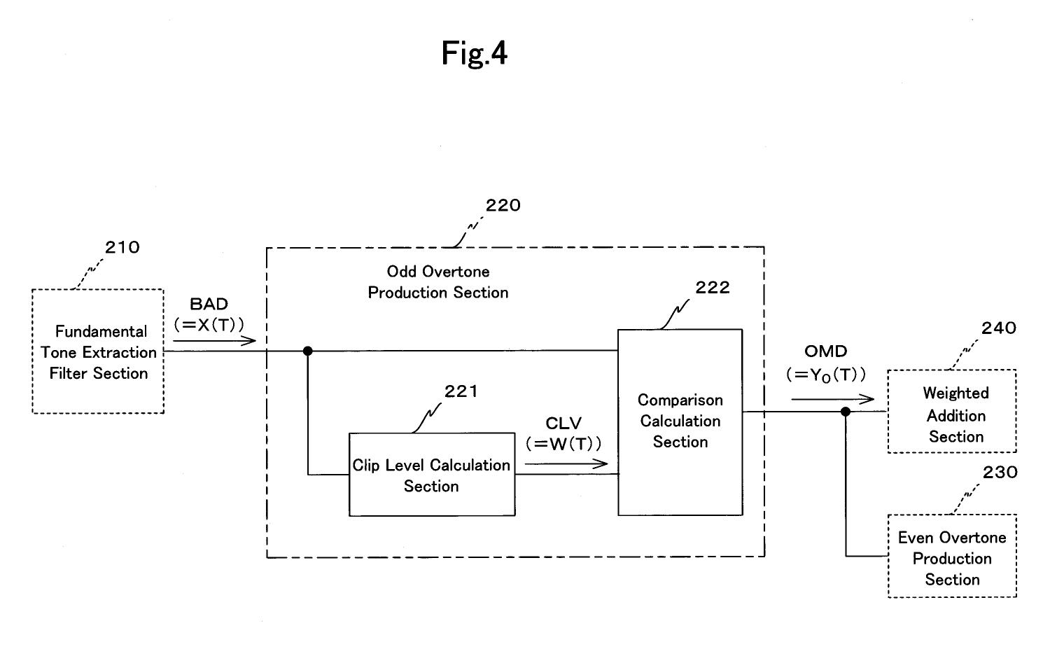

The odd overtone production section 220 described above receives the signal BAD (=X(T)) from the fundamental tone extraction filter section 210. And the odd overtone production section 220 generates approximately odd overtones including non-integral multiple frequency components that are deviated more or less with respect to the odd harmonic frequencies of the signal BAD (=X(T)). As shown in FIG. 4, this odd overtone production section 220 comprises a clip level calculation section 221 that serves as a calculation means, and a comparison calculation section 222 that serves as a clipping means.

The clip level calculation section 221 described above receives this signal BAD (=X(T)) from the fundamental tone extraction filter section 210. And, on the basis of the current clip level W(T) which was calculated the time before and the signal X(T), the clip level calculation section 221 calculates a clip level (T+T), which is an updated value for the current clip level W(T).

During this calculation of the clip level W(T), the clip level calculation section 221 first calculates an error E(T) according to the following Equation (2):

E(T)=V·|X(T)|−W(T) (2)

Here V is a constant less than unity, which is determined in advance.

It should be understood that this constant V is determined in advance on the basis of experiment, simulation, experience, or the like, from the standpoint of the amount of overtones to be generated.

Next, the clip level calculation section 221 calculates the clip level W(T+τ) to be employed at the time instant T(T+τ), according to the following Equation (3):

W(T+τ)=W(T)+W(T)·|X(T)|·μ·E(T) (3)

Here, μ is a constant which is determined in advance.

It should be understood that this constant μ is determined in advance on the basis of experiment, simulation, experience, or the like, from the standpoints of preventing divergence of the result of clip level calculation, and of the speed of convergence.

In other words, the clip level calculation section 221 calculates the clip level repeatedly, and updates the clip level, so that the error gradually approaches zero. The current clip level W(T) that has been calculated the previous time in this manner is sent as a signal CLV to the comparison calculation section 222.

The comparison calculation section 222 described above receives the signal BAD (=X(T)) from the fundamental tone extraction filter section 210 and the signal CLV (=W(T)) from the clip level calculation section 221. And the comparison calculation section 222 performs clipping processing upon the signal X(T), on the basis of the clip level W(T).

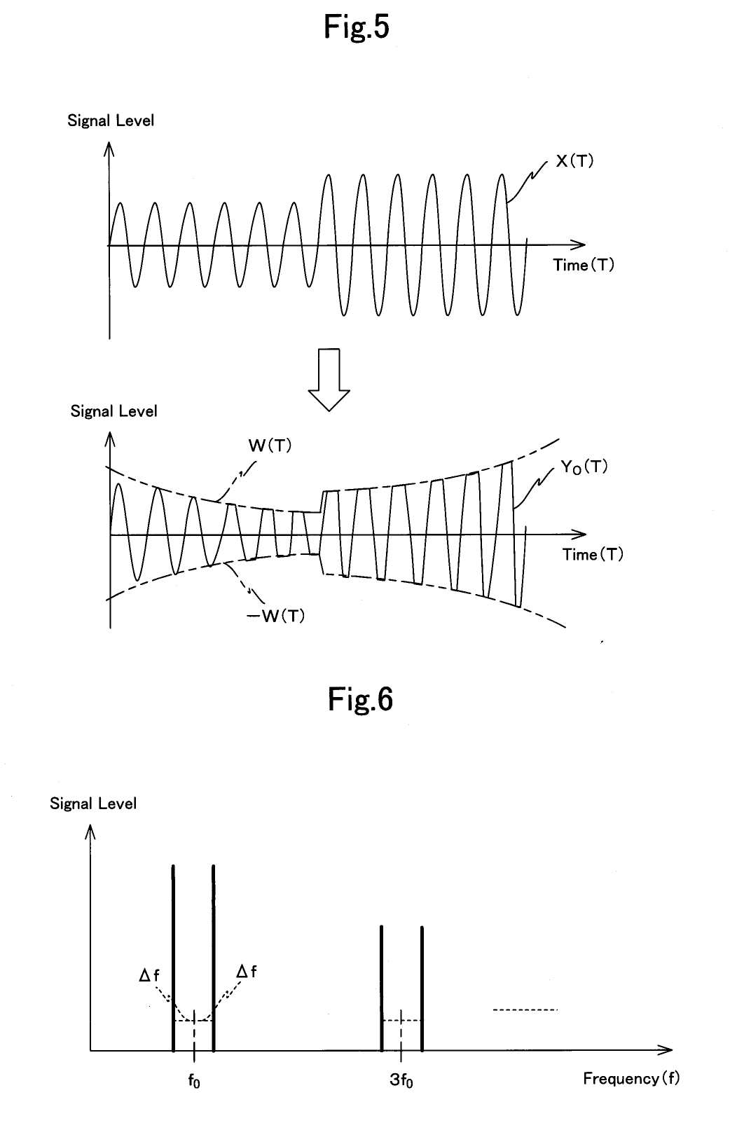

In other words, if the value of the signal X(T) (hereinafter, sometimes also termed the “value X(T)”) is greater than or equal to zero, then the comparison calculation section 222 uses that one of the value X(T) and the value of the signal W(T) (hereinafter, sometimes also termed the “value W(T)”) that is the closer to zero as the value of the signal OMD (=Y_{O}(T)). On the other hand, if the value X(T) is negative, then that one of the value X(T) and the value (−W(T)) which is the closer to zero is used as the value of the signal OMD. The comparison calculation section 222 performs clipping processing upon the signal X(T) in this manner. An example of clipping processing when the signal level changes while the signal X(T) has a constant frequency will be shown in FIG. 5.

Now, as described above, the clip level W(T) changes with time, although generally gradually. If this change of the clip level W(T) is at the frequency Δf, then the frequency distribution of the signal Y_{O}(T) is shown in FIG. 6. In this case, as shown in FIG. 6, the signal Y_{O}(T) includes components of frequencies [(2j−1)·f₀−Δf], [(2j−1)·f₀+Δf], . . . (for j=1, 2, . . . ). In other words, the signal Y_{O}(T) includes approximate odd overtones which are non-integral multiple frequency components that deviate only a little in frequency with respect to the odd numbered harmonic frequencies of the signal X(T), according to change of the clip level W(T). It should be understood that, if the clip level W(T) is constant, then the signal Y_{O}(T) includes odd numbered harmonic frequency components accurately.

It should be understood that, in this specification, the term “odd overtone” will be used as a generic term to refer both to a frequency component which is approximately an odd numbered harmonic component, and also to a frequency component which is exactly an odd numbered harmonic frequency component.

The signal OMD (=Y_{O}(T)) that is generated in this manner is sent to the even overtone production section 230 and the weighted addition section 240.

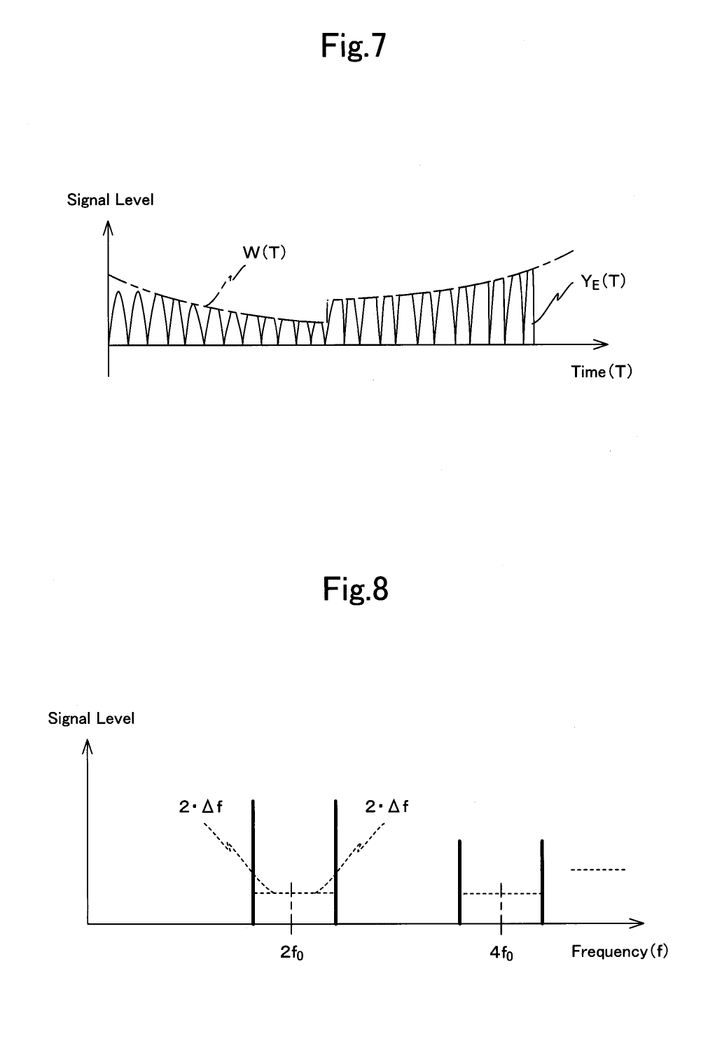

Returning to FIG. 3, the even overtone production section 230 receives the signal OMD (=Y_{O}(T)) from the odd overtone production section 220. And the even overtone production section 230 generates a signal EMD (=Y_{E}(T)) that includes approximately even overtones including non-integral multiple frequency components that are deviated more or less with respect to the even numbered harmonic frequencies of the signal X(T). During the generation of this signal EMD, it is arranged for the even overtone production section 230 to perform full wave communication processing upon the signal Y_{O}(T). An example of the waveform of the signal Y_{E}(T) that is generated in this manner will be shown in FIG. 7.

Furthermore, an example of the approximately even overtones included in this signal Y_{E}(T) is shown in FIG. 8 as a frequency distribution. As shown in FIG. 8, this signal Y_{E}(T) includes components of frequencies [2j·f₀−2·Δf], [2j·f₀+2·Δf], (for j=1, 2, . . . ). In other words, the signal Y_{E}(T) includes approximate even overtones which are non-integral multiple frequency components that deviate only a little in frequency with respect to the even numbered harmonic frequencies of the signal X(T), according to change of the clip level W(T). It should be understood that, if the clip level W(T) is constant, then the signal Y_{E}(T) includes even numbered harmonic frequency components accurately.

It should be understood that, in this specification, the term “even overtone” will be used as a generic term to refer both to a frequency component which is approximately an even numbered harmonic component, and also to a frequency component which is exactly an even numbered harmonic frequency component.

The signal EMD (=Y_{E}(T)) that is generated in this manner is sent to the weighted addition section 240.

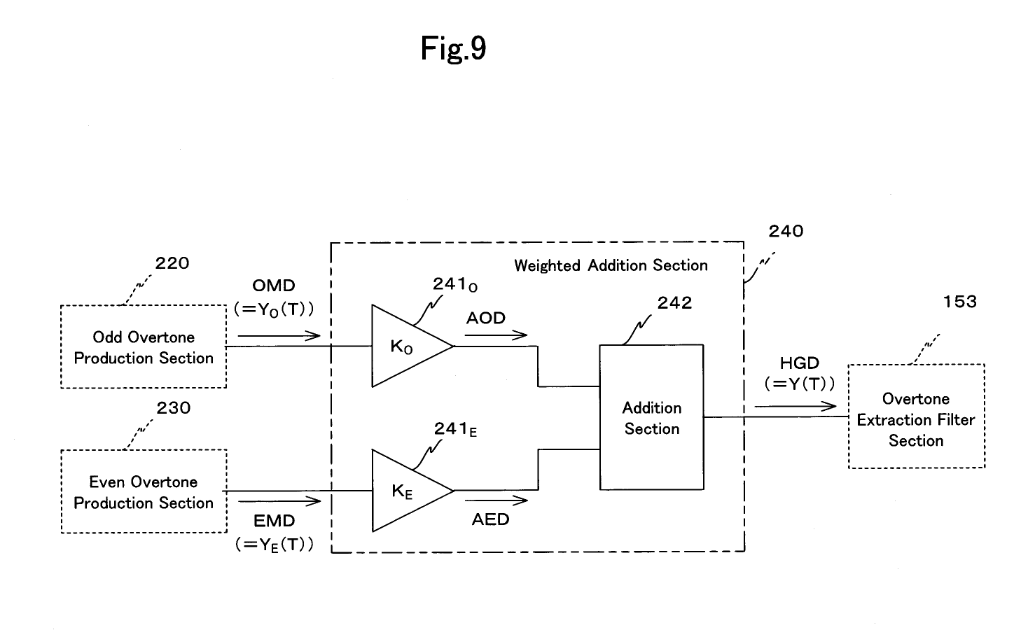

Returning to FIG. 3, the weighted addition section 240 receives the signal OMD (=Y_{O}(T)) from the odd overtone production section 220 and the signal EMD (=Y_{E}(T)) from the even overtone production section 230. And the weighted addition section 240 performs weighted addition of the signal Y_{O}(T) and the signal Y_{E}(T). As shown in FIG. 9, this weighted addition section 240 comprises an attenuation section 241_{O}, an attenuation section 241_{E}, and an addition section 242.

The above described attenuation section 241_{O} receives the signal OMD (=Y_{O}(T)) from the odd overtone production section 220. And the attenuation section 241_{O} attenuates this signal Y_{O}(T) at an attenuation ratio K_{O}. The result of this attenuation is sent to the addition section 242 as a signal AOD.

It should be understood that this attenuation ratio K_{O} is determined in advance on the basis of experiment, simulation, experience, or the like, from the standpoint of providing appropriate boosting of the odd overtone frequency bands.

Similarly, the above described attenuation section 241_{E} receives the signal EMD (=Y_{E}(T)) from the even overtone production section 230. And the attenuation section 241_{E} attenuates this signal Y_{E}(T) at an attenuation ratio K_{E}. The result of this attenuation is sent to the addition section 242 as a signal AED.

It should be understood that this attenuation ratio K_{E} is determined in advance on the basis of experiment, simulation, experience, or the like, from the standpoint of providing appropriate boosting of the even overtone frequency bands.

The addition section 242 receives the signal AOD from the attenuation section 241_{O} and the signal AED from the attenuation section 241_{E}. And the addition section 242 adds together the signal AOD and the signal AED, thus generating a signal HGD (=Y(T)).

The signal HGD (=Y(T)) that is the result of this addition by the addition section 242 is sent to the overtone extraction filter section 153.

Returning to FIG. 2, the above described overtone extraction filter section 153 receives the signal HGD (=Y(T)) from the overtone production device 152. And the overtone extraction filter section 153 extracts the desired overtone components in the signal Y(T).

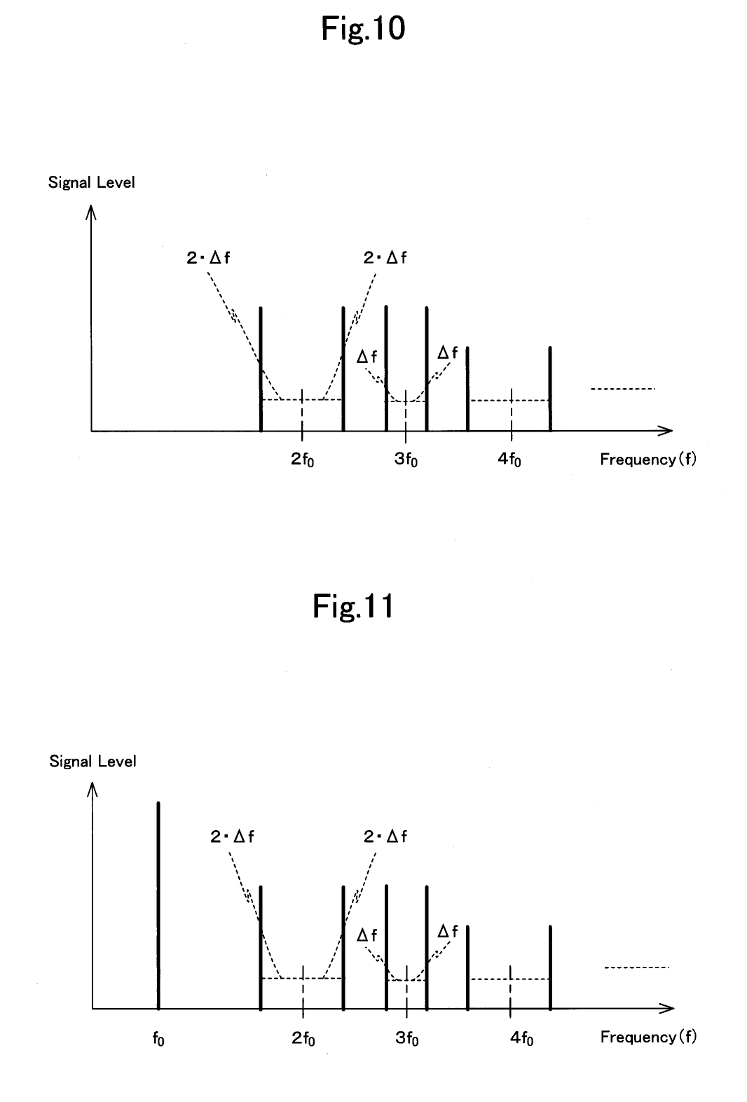

In this embodiment, the overtone extraction filter section 153 not only passes through all the odd overtone components and even overtone components in the signal Y(T), but also is built as a high pass filter that intercepts the component in the fundamental tone frequency band, which is the frequency band of the signal BAD (=X(T)). An example of the odd overtones and even overtones that are included in the signal HPD (=M(T)) extracted by the overtone extraction filter section 153 is shown in FIG. 10 as a frequency distribution.

This signal HPD (=M(T)) that has been extracted by the overtone extraction filter section 153 is fed to the addition section 154.

The addition section 154 described above receives the signal DLD (=D(T)) from the delay section 151 and the signal HPD (=M(T)) from the overtone extraction filter section 153. And the addition section 154 calculates the sum of these signals D(T) and M(T), and thereby generates a signal HID (=S(T)). An example of the frequency components that are included in this signal S(T) is shown in FIG. 11 as a frequency distribution.

This signal HID (=S(T)) that is the result of addition by the addition section 254 is fed to the analog processing unit 160.

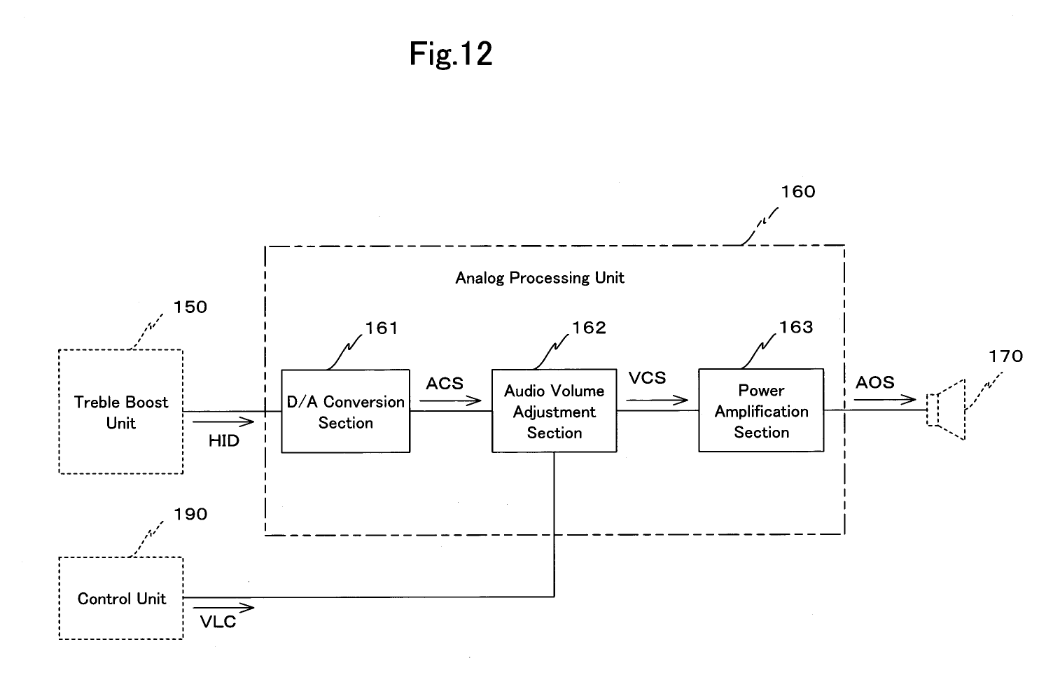

Returning to FIG. 1, the analog processing unit 160 described above receives the signal HID from the treble boost unit 150. And, based upon control by the control unit 190, the analog processing unit 160 generates an output audio signal AOS, which it feeds to the speaker unit 170. As shown in FIG. 12, this analog processing unit 160 having the above function comprises a D/A (Digital to Analog) conversion section 161, an audio volume adjustment section 162, and a power amplification section 163.

The D/A conversion section 161 described above receives the signal HID from the treble boost unit 150. And the D/A conversion section 161 converts this signal HID into an analog signal. This D/A conversion section 161 comprises two D/A (Digital to Analog) converters that are both structured in a similar manner, corresponding to a left channel (hereinafter termed the “L channel”) signal and a right channel (hereinafter termed the “R channel”) signal that are included in the signal HID. The analog signal ACS that is the result of this conversion by the D/A conversion section 161 is sent to an audio volume adjustment section 162.

The audio volume adjustment section 162 described above receives the analog signal ACS from the D/A conversion section 161. And, according to an audio volume adjustment command VLC from the control unit 190, the audio volume adjustment section 162 performs audio volume adjustment processing upon this analog signal ACS. In this embodiment, this audio volume adjustment section 162 comprises two electronic volume elements and so on that are both structured in a similar manner, corresponding to the L channel signal and the R channel signal that are included in the analog signal ACS. The analog signal VCS that is the result of this adjustment by the audio volume adjustment section 162 is sent to the power amplification section 163.

The power amplification section 163 described above receives the analog signal VCS from the audio volume adjustment section 162. And the power amplification section 163 amplifies the power of the analog signal VCS. This power amplification section 163 comprises two power amplifiers which are structured in a mutually similar manner, corresponding to the L channel signal and the R channel signal included in the analog signal VCS. An output audio signal AOS, which is the result of this amplification by the power amplification section 163, is fed to the speaker unit 170.

Returning to FIG. 1, the speaker unit 170 comprises a L channel speaker and a R channel speaker. This speaker unit 170 replay outputs audio according to the output signal AOS from the analog processing unit 160.

The operation input unit 180 is composed of a key section that is provided in the main body section of the acoustic device 100, or of a remote input device that comprises a key section, or the like. Moreover, as such a key section that is provided to the main body section, it would be possible to utilize a touch panel provided to a display unit that is not shown in the figures. Furthermore, instead of providing a key section, it would also be possible to employ a structure that accepts audio input. The result of operation input to the operation input unit 180 is sent to the control unit 190 as operation input data IPD.

The control unit 190 analyzes the operation input data IPD from the operation input unit 180. And, if the content of the operation input data IPD is a specification of details for front end processing, then the control unit 190 issues a front end processing control command PPC that corresponds to these specified details for front end processing, and sends this command to the front end processing unit 140. Furthermore, if the content of the operation input data IPD is a specification for audio volume adjustment that includes a manner for audio volume adjustment mode, then the control unit 190 issues an audio volume adjustment command VLC that corresponds to this designated audio volume adjustment manner, and sends this command to the analog processing unit 160.

### [Operation]

Next, the operation of this acoustic device having the structure described above will be explained, with attention principally being directed to the signal processing that is performed by the treble boost unit 150.

As a preliminary, it will be supposed that a front end processing command has already been inputted by the user via the operation input unit 180, and that a front end processing control command PPC corresponding to the front end processing that has been designated has been sent to the front end processing unit 140. Moreover, it will be supposed that an audio volume adjustment command has already been inputted by the user via the operation input unit 170, and that an audio volume adjustment command VLC corresponding to the audio volume adjustment mode that has been designated has been sent to the analog processing unit 160 (refer to FIG. 1).

When, in this state, a signal OAD is outputted from the audio source unit 110 on the basis of some audio contents, the DIR 120 converts it to a signal CPD of a predetermined format. Subsequently, the data expansion unit 130 performs data decompression processing upon the signal CPD to cancel its data compression. And, according to a front end processing control command PPC from the control unit 190, the front end processing unit 140 then performs front end processing such as mixing processing and so on upon the signal EPD, and sends the result to the treble boost unit 150 as the signal PPD (refer to FIG. 1).

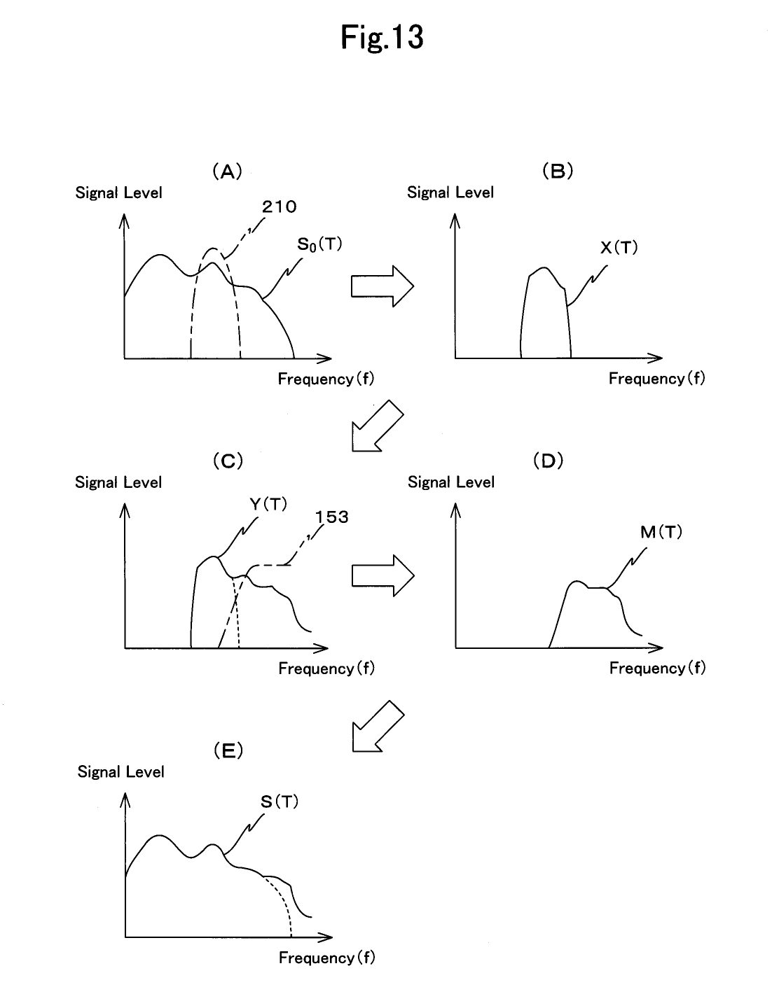

In the treble boost unit 150, the signal PPD (=S_{O}(T): an example of its frequency distribution is shown in FIG. 13(A)) is received by the delay section 151 and the overtone production device 152. Upon receipt of this signal PPD (=S_{O}(T)), the delay section 151 generates the signal DLD (=D(T)), which is the signal S_{O}(T) delayed by just the time period T_{DL} for processing by the overtone production device 152 and the overtone extraction filter section 153, and sends the signal DLD to the addition section 154 (refer to FIG. 2).

On the other hand, in the overtone production device 152, the signal PPD (=S_{O}(T)) is received by the fundamental tone extraction filter section 210 (refer to FIG. 3). Upon receipt of this signal S_{O}(T), the fundamental tone extraction filter section 210 extracts from the signal S_{O}(T) the signal BAD (=X(T)) of the fundamental tone component, which is to be the subject of generation of overtones (refer to FIGS. 13(A) and 13(B)). In this manner, the signal BAD (=X(T)) is sent to the odd overtone production section 220 (refer to FIG. 3).

In the odd overtone production section 220, the signal BAD (=X(T)) is received by the clip level calculation section 221 and the comparison calculation section 222. Upon receipt of the signal X(T), the clip level calculation section 221 first calculates the error E(T) according to Equation (2) described above. Subsequently, the clip level calculation section 221 calculates an updated value for the clip level according to Equation (3) described above. It should be understood that the current clip level W(T) that has been calculated by the clip level calculation section 221 the time before is sent to the comparison calculation section 222 as the signal CLV (refer to FIG. 4).

Upon receipt of the signal BAD (=X(T)) and the signal CLV (=W(T)), the comparison calculation section 222 performs clipping processing upon the signal X(T) on the basis of the clip level W(T). The signal OMD (=YO(T)) including odd overtones of the signal X(T) generated as a result of this clipping processing is sent to the even overtone production section 230 and the weighted addition section 240 (refer to FIG. 4).

Upon receipt of this signal OMD (=Y(T)), the even overtone production section 230 performs full wave rectification processing upon this signal Y(T). The resulting signal EMD (=Y_{E}(T)) generated by this full wave rectification processing that includes even overtones of the signal X(T) is sent to the weighted addition section 240 (refer to FIG. 3).

Upon receipt of the signal OMD (=Y_{O}(T)) from the odd overtone production section 220 and the signal EMD (=Y_{E}(T)) from the even overtone production section 230, in the weighted addition section 240, the signal AOD is generated by the attenuation section 241_{O} attenuating the signal Y_{O}(T) by the attenuation ratio K_{O}, and also the signal AED is generated by the attenuation section 241_{E} attenuating the signal Y_{E}(T) by the attenuation ratio K_{E}. And the addition section 242 performs weighted addition of the signal Y_{O}(T) and the signal Y_{E}(T), and thereby generates the signal HGD (=Y(T)) (refer to FIG. 13(C)). The signal HGD (=Y(T)) that has been generated in this manner is sent to the overtone extraction filter section 153 (refer to FIG. 9).

Upon receipt of this signal HGD (=Y(T)), the overtone extraction filter section 153 extracts the overtone component in the signal Y(T), and generates the signal HPD (=M(T)) (refer to FIGS. 13(C) and 13(D)). The signal HPD (=M(T)) that has been generated in this manner is sent to the addition section 154 (refer to FIG. 2).

Upon receipt of the signal DLD(T) (=D(T)) from the delay section 151 and the signal HPD (=M(T)) from the overtone extraction filter section 153, the addition section 154 calculates the sum of these signals D(T) and M(T), and creates the signal HID (=S(T)). As shown in FIG. 13(E), this signal S(T) is one in which the treble is increased in strength, as compared to the signal S_{O}(T) that corresponds to the audio contents. The signal HID that has been created in this manner is sent to the analog processing unit 160 (refer to FIG. 1).

Upon receipt of this signal HID from the treble boost unit 150, in the analog processing unit 160, first, the D/A conversion section 161 converts this signal HID into the analog signal ACS. Subsequently, according to an audio volume adjustment command VLC from the control unit 190, the audio volume adjustment section 162 performs audio volume adjustment processing upon this analog signal ACS, and then sends it to the power amplification section 163 as the analog signal VCS (refer to FIG. 12).

And, upon receipt of this analog signal VCS, the power amplification section 163 power amplifies this analog signal VCS to generate the output audio signal AOS, and then sends it to the speaker unit 170 (refer to FIG. 12). And, according to this audio signal AOS outputted from the analog processing unit 160, the speaker unit 170 replay outputs audio.

As has been explained above, in this embodiment, during treble boosting, first the signal X(T) of the fundamental tone component that is to be the subject of production of overtones is extracted by the fundamental tone extraction filter section 210 from the signal S_{O}(T) that is to be the subject of boosting. Subsequently, the clip level calculation section 221 calculates a clip level on the basis of the signal X(T). And the comparison calculation section 222 performs clipping processing upon the signal X(T) on the basis of this clip level W(T), and thereby generates a signal that includes overtone components. By doing this, it is possible to generate overtones without performing any division computation.

Thus, according to this embodiment, it is possible to generate appropriate overtones in a reliable manner during reinforcement of the treble register, in a way which is suitable for digital signal processing, and moreover in which the sense of discomfort from the point of view of the listener is low.

Furthermore, in this embodiment, since the clip level calculation section 221 calculates the clip level on the basis of the signal X(T), accordingly the clip level W(T) changes only gently. Due to this, it is possible to generate overtones having frequencies that are non-integral multiples of the frequency of the fundamental tone component.

### Modified Embodiments

The present invention is not to be considered as being limited to the embodiment described above; many variations are possible.

For example while, in the embodiment described above, the overtone extraction filter section 153 was constructed as a high pass filter, it would also be possible to construct this section 153 as a band pass filter that allows only the desired overtone components to pass.

Furthermore while, with the embodiment described above, it was arranged to determine in advance the values of parameters of various types that regulate the operational mode of the treble boost unit 150, it would also be acceptable to arrange for it to be possible, in response to command input to the operation input unit 180, for the control unit 190 to issue commands to the treble boost unit 150 including the values of at least some of these parameters of various types. As these parameters of various types, the constant V in Equation (2) and the constant μ in Equation (3) that are utilized by the clip level calculation section, the attenuation ratios K_{O} and K_{E} that are used by the weighted addition section 240, the filter characteristics of the fundamental tone extraction filter section 210 and the overtone extraction filter section 153, and so on may be cited.

Furthermore, while in the embodiment described above it is arranged to update the clip level W(T) using Equation (3) so that the error E(T) approaches zero, it would also be acceptable to arrange to update the clip level W(T) according to Equation (4) below, so that the square of the error E(T) approaches zero:

W(T+τ)=W(T)+W(T)·|X(T)|·λ·[E(T)]² (4)

Here, λ is a constant which is determined in advance.

Yet further, in the embodiment described above, it is arranged to update the clip level W(T) using Equation (3), so that the error E(T) approaches zero. By contrast, it would also be acceptable to arrange to update the clip level W(T) according to the following Equation (5) by employing the average value of a predetermined number of samples N (>2) of the most recent signal BAD (=X(T)), as the clip level W(T).

W(T)=[X(T)+X(T−τ)+ . . . +X(T−(N−1)·τ)]/N (5)

Furthermore, while in the embodiment described above it was supposed that the audio contents were recorded upon a recording medium, it would also be possible to apply the present invention in the case of receiving and replaying broadcast audio contents.

It should be understood that it would also be acceptable to arrange for the treble boost unit 150 of the embodiment described above to be constituted as a computer whose calculation means comprises a DSP (Digital Signal Processor) and so on, and for a part or the entirety of the processing of the embodiment described above to be executed by that computer executing a program that is prepared in advance. This program would be recorded upon a computer-readable recording medium such as a hard disk, a CD-ROM, a DVD or the like and would be read out and executed by that computer from the recording medium. Moreover, it would also be acceptable to arrange for this program to be acquired by being recorded upon a transportable recording medium such as a CD-ROM, a DVD or the like, or to be acquired by being transmitted over a network such as the internet or the like.

1-10. (canceled)

11. An overtone production device which produces overtones of a component of a predetermined frequency range included in an audio signal, characterized by comprising:
an extraction part configures to extract said component of said predetermined frequency range from said audio signal;
a calculation part configures to calculate a clip level corresponding to the signal level of the signal extracted by said extraction part;
a clipping part configures to generate a clipped signal by performing clipping processing upon said extracted signal, on the basis of the clip level calculated by said calculation part; and
said calculation part configures to calculate a new clip level value on the basis of the value of the error between the result of multiplying the current value of the signal level of said extracted signal by a predetermined reference value, and the current value of said clip level.

12. An overtone production device according to claim 11, characterized by further comprising an even overtone production part configures to produce even overtone signals of said extracted signal, on the basis of said clip signal.

13. An overtone production device according to claim 12, characterized in that said even overtone production part configures to perform full wave rectification of said clip signal.

14. An overtone production device according to claim 12, characterized by further comprising an addition part configures to perform weighted addition of said clip signal and said even overtone signal.

15. An acoustic device, characterized by comprising:
an overtone production device according to claim 11, which produces overtones of a component of a predetermined frequency range included in an audio signal;
an overtone extraction part configures to extract a predetermined overtone component in the overtone signal produced by said overtone production device; and
an overtone addition part configures to add together said audio signal and said signal extracted by said overtone extraction part.

16. An overtone production method, characterized by comprising:
an extraction process of extracting a component of a predetermined frequency range from an audio signal;
a calculation process of calculating a clip level corresponding to the signal level of the signal extracted by said extraction part;
a clipping process of performing clipping processing upon said extracted signal, on the basis of the clip level calculated by said calculation process and
in that said calculation process, a new clip level value is calculated on the basis of the value of the error between the result of multiplying the current value of the signal level of said extracted signal by a predetermined reference value, and the current value of said clip level.

17. An overtone production program, characterized by causing a calculation part configures to execute an overtone production method according to claim 16.

18. A recording medium, characterized in that an overtone production program according to claim 17 is recorded thereupon so as to be readable by a calculation part.

19. An overtone production device according to claim 13, characterized by further comprising an addition part configures to perform weighted addition of said clip signal and said even overtone signal.

20. An acoustic device, characterized by comprising:
an overtone production device according to claim 12, which produces overtones of a component of a predetermined frequency range included in an audio signal;
an overtone extraction part configures to extract a predetermined overtone component in the overtone signal produced by said overtone production device; and
an overtone addition part configures to add together said audio signal and said signal extracted by said overtone extraction part.

21. An acoustic device, characterized by comprising:
an overtone production device according to claim 13, which produces overtones of a component of a predetermined frequency range included in an audio signal;
an overtone extraction part configures to extract a predetermined overtone component in the overtone signal produced by said overtone production device; and
an overtone addition part configures to add together said audio signal and said signal extracted by said overtone extraction part.

22. An acoustic device, characterized by comprising:
an overtone production device according to claim 14, which produces overtones of a component of a predetermined frequency range included in an audio signal;
an overtone extraction part configures to extract a predetermined overtone component in the overtone signal produced by said overtone production device; and
an overtone addition part configures to add together said audio signal and said signal extracted by said overtone extraction part.
